(19) United States
(12) Patent Application Publication
(10) Pub. No.: US 2023/0216275 A1
(43) Pub. Date: Jul. 6, 2023

(54) SEMICONDUCTOR LIGHT-EMITTING ELEMENT, LIGHT-EMITTING DEVICE, AND RANGING DEVICE

(71) Applicant: CANON KABUSHIKI KAISHA, Tokyo (JP)

(72) Inventors: TAKAKO SUGA, Kanagawa (JP); TAKESHI UCHIDA, Kanagawa (JP); TATSURO UCHIDA, Tokyo (JP)

(21) Appl. No.: 18/145,547

(22) Filed: Dec. 22, 2022

(30) Foreign Application Priority Data
Jan. 1, 2022 (JP) 2022-000026

(51) Int. Cl. H01S 5/183; H01S 5/30

(52) U.S. Cl. CPC H01S 5/18311; H01S 5/18333; H01S 5/3095; H01S 5/18369; G01S 7/4814

(57) ABSTRACT

A semiconductor light-emitting element having a structure in which a substrate, a first reflector, a resonator cavity including an active layer, a second reflector and a tunnel junction portion are stacked in this sequence, comprising: a first current constriction portion configured with an oxidation constriction layer; and a second current constriction portion including the tunnel junction portion, wherein a width d2 of the second current constriction portion is smaller than a width d1 of the first current constriction portion.

### BACKGROUND OF THE INVENTION

### Field of the Invention

The present invention relates to a semiconductor light-emitting element, a light-emitting device, and a ranging device.

### Description of the Related Art

A vertical cavity surface-emitting laser (VCSEL) is receiving attention as a light source for a time-of-flight (ToF) type light detection and ranging (LiDAR).

Higher power is demanded for the light sources in order to improve ranging accuracy and to increase a measurable distance.

A possible method for implementing high power in VCSEL is increasing a light-emitting diameter. Simply increasing a light-emitting diameter, however, decreases the current density in a portion around the center of the light-emitting diameter, and increases the current density in a peripheral portion thereof. In other words, merely increasing the light-emitting diameter causes problems in beam control of a far field and in durability.

WO 2019/107273 discloses a substrate rear face-emitting type VCSEL, where a current constriction structure, which is different from the oxidation constriction, is disposed on the front face side of the substrate. By this configuration, current density not only in a peripheral portion but also in the portion around the center of the light-emitting diameter can be increased, while increasing the light-emitting diameter. However, in the case of the substrate rear face-emitting type VCSEL, light is absorbed by the substrate, hence this implementation may not be possible depending on the wavelength or high power may not be achieved.

Japanese Patent Application Publication No. 2006-114915 discloses a substrate front face-emitting type VCSEL where the current constriction structure, which is different from the oxidation constriction, is disposed on the front face of the device, which is the light-emitting side, by diffusion or ion implantation. By increasing the light-emitting diameter using this configuration as well, the current density can be increased not only in the peripheral portion but also in the portion around the center of the light-emitting diameter.

Japanese Patent Application Publication No. 2006-114915 also discloses a method for forming a current constriction structure in which current flows only through the center portion, by implanting ions into the peripheral portion on the substrate front face, so as to increase the resistance of the peripheral portion. A problem that is generated in the case of forming the current constriction structure like this will be described with reference to FIG. 13.

In FIG. 13, a high resistance region 712 is formed on a peripheral portion in a p-GaAs layer 710 by ion implantation, and in an upper portion inside the p-GaAs layer 710, a current path from a second electrode 714 to a current injection region 720 remains. Then a current path from the current injection region 720 to the opening 716 is formed in a p-DBR 708. For these reasons, the thickness of the p-GaAs layer 710 needs to be formed in the μm order. Since the distance of the current injection region 720 in the vertical direction of the substrate becomes thick (μm order), the resistance increases, and as a result, the voltage of the entire semiconductor light-emitting element increases.

### SUMMARY OF THE INVENTION

With the foregoing in view, it is an object of the present invention to provide a semiconductor light-emitting element that easily controls beams in a far field at high power, while restraining an increase of voltage in the entire element.

The first aspect of the present invention is a semiconductor light-emitting element having a structure in which a substrate, a first reflector, a resonator cavity including an active layer, a second reflector and a tunnel junction portion are stacked in this sequence, comprising: a first current constriction portion configured with an oxidation constriction layer; and a second current constriction portion including the tunnel junction portion, wherein a width d2 of the second current constriction portion is smaller than a width d1 of the first current constriction portion.

According to the present invention, a semiconductor light-emitting element that easily controls beams in a far field at high power can be provide, while restraining an increase of voltage in the entire element. By using this semiconductor light-emitting element, a ranging device, which improves ranging accuracy and measurable distance, can be provided.

Further features of the present invention will become apparent from the following description of exemplary embodiments with reference to the attached drawings.

### BRIEF DESCRIPTION OF THE DRAWINGS

FIG. 1 is a diagram depicting a semiconductor light-emitting element of a present embodiment;

FIGS. 2A and 2B are graphs indicating distribution and change of current density according to the present embodiment;

FIG. 3 is a diagram depicting Example 1;

FIG. 4A is a diagram depicting Example 2;

FIG. 4B is a diagram depicting a modification of Example 2;

FIG. 4C is a diagram depicting another modification of Example 2;

FIGS. 5A to 5C are diagrams depicting Example 3;

FIG. 6 is a diagram depicting Example 4;

FIGS. 7A and 7B are graphs indicating distribution and change of current density according to Example 4;

FIG. 8 is a diagram depicting Example 5;

FIG. 9 is a diagram depicting Example 6;

FIG. 10 is a diagram depicting Example 7;

FIG. 11 is a diagram depicting Example 8;

FIG. 12 is a diagram depicting Example 9; and

FIG. 13 is a diagram depicting a comparative example.

### DESCRIPTION OF THE EMBODIMENTS

Embodiments of the present invention will be described. The present invention is not limited to the following embodiments, and includes changes and modifications performed on the following embodiments based on common knowledge of an expert skilled in the art, without departing from the spirit and scope of the present invention.

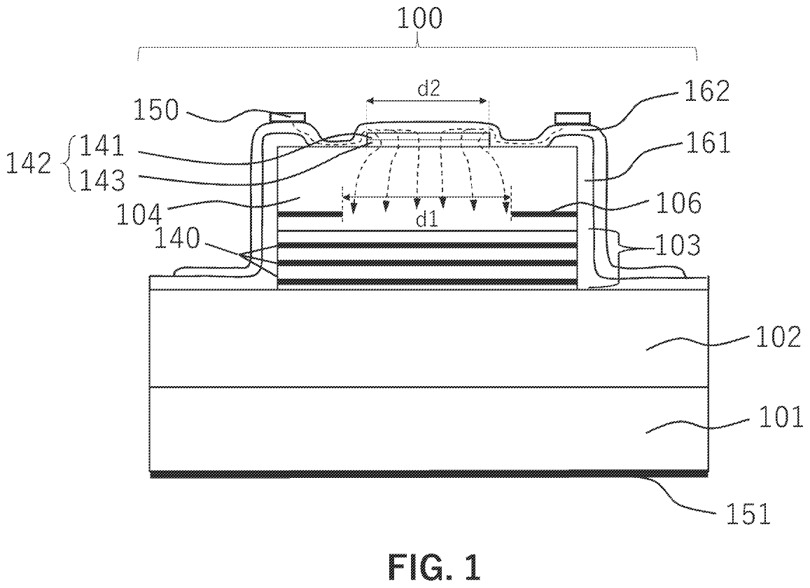

A semiconductor light-emitting element 100 according to an embodiment of the present invention will be described with reference to FIG. 1. The semiconductor light-emitting element 100 includes: a substrate 101, a first distributed Bragg reflector (DBR) 102, a semiconductor resonator cavity 103, a second DBR 104 and a tunnel junction layer 142. The first DBR 102 and the second DBR 104 correspond to the first reflector and the second reflector of the present invention respectively.

The substrate 101 and the first DBR 102 are formed of an n-type semiconductor, and the second DBR 104 is formed of a p-type semiconductor. A lower electrode 151 is in ohmic contact with the rear face of the substrate 101.

A plurality of quantum well layers 140 are disposed in the resonator cavity 103. An AlGaAs layer, of which Al composition is higher than the other layers, is included in a part of the second DBR 104. An oxidation constriction layer 106, of which periphery is insulated by performing steam oxidation on these layers, is formed on an outer periphery portion. The oxidation constriction layer 106 corresponds to the first current constriction portion. In FIG. 1, only the insulated portion is indicated by the reference number 106, but the non-oxidized center portion of the semiconductor layer also corresponds to the oxidation constriction layer 106.

In the present embodiment, the second DBR 104 is formed of a semiconductor. As another mode of the present invention, a third, fourth or fifth DBR, which is different from the second DBR, may be disposed on the second DBR, or other modifications thereof may be possible. Details thereof will be described later in Examples 2 and 7.

The resonator cavity 103 and the second DBR 104 are processed to be tubular mesa-shaped. In FIG. 1, the mesa shape is formed from the second DBR 104 to the resonator cavity 103, but required here is that the mesa shape is formed at a depth lower than the oxidation constriction layer 106. This means that the mesa shape may be formed at a depth in the middle of the resonator cavity 103, or may be formed at a depth in the middle of the first DBR 102.

The present embodiment describes a structure in which the light-emitting element is processed in the tubular mesa shape, but the present invention is not limited thereto. For example, instead of uniformly processing the periphery to be a tubular shape, the oxidation constriction layer 106 may be formed by removing a part of the portion down to a target depth by etching, and then the periphery is insulated by steam oxidation.

When a high refractive index layer and a low refractive index layer, of which optical thicknesses are both λc/4, form a pair, the first DBR 102 is configured with a plurality of pairs that are stacked. λc is a central wavelength of the high reflection band of the first DBR 102.

The quantum well layer 140 has a configuration where a well layer is sandwiched by barrier layers, and is an active layer of the resonator cavity 103.

When a high refractive index layer and a low refractive index layer, of which both optical film thicknesses are both λc/4, form a pair, the second DBR 104 is configured with a plurality of pairs that are stacked. A part of the high refractive index layer closest to the quantum well layer (active layer) 140 of the second DBR 104, however, is replaced with an AlGaAs layer of which Al composition is higher than the other layers. After the mesa of the VCSEL 100 is formed, this AlGaAs layer is oxidized from the side wall of the mesa for a predetermined length from the side wall of the mesa by steam oxidation, whereby the oxidation constriction layer 106 having insulation properties is formed on the periphery thereof.

The tunnel junction layer 142 is configured with at least two layers, that is, a high doped p-type semiconductor layer 143 and a high doped n-type semiconductor layer 141 thereon from the substrate 101 side. The total optical film thickness of these two layers is set to an integral multiple of λc/2.

In the case where absorption in a high doped p-type GaAs layer is a problem, the p-type semiconductor layer 143 may be configured with a plurality of layers. For example, a two-layer configuration of a layer on the substrate side, which has a lower doping concentration and a layer thereon (layer that is in contact with the n-type semiconductor layer 141) which has a thin high doped layer, may be used.

The tunnel junction layer 142 is patterned so as to be formed on a part of the upper face of the second DBR 104. Specifically, the tunnel junction layer 142 is formed so that the center portion of the tunnel junction layer 142 matches with the center portion of the second DBR 104, which more specifically is the center of the oxidation constriction (center of the non-oxidized portion) formed by the oxidation constriction layer 106. In the present embodiment, the shape of the tunnel junction layer 142 is a circle, but may be a different shape, such as a polygon. The width of the tunnel junction layer (the diameter if the tunnel junction layer is a circle) is d2. The tunnel junction layer 142 is formed so as to be included inside the constriction portion (non-oxidized portion) formed by the oxidation constriction layer 106 in the planar view. The carriers supplied from an upper ring electrode 150 are supplied from the portion, in which the tunnel junction layer 142 exists, to the second DBR 104. This means that the tunnel junction portion having this tunnel junction layer 142 corresponds to the second current constriction portion. In the present description, the tunnel junction portion does not refer to the junction interface between the p-type semiconductor layer and the n-type semiconductor layer having high impurity concentration, but to a member which includes these semiconductor layers.

Whereas FIG. 1 is an example when the tunnel junction layer is patterned to form the second current constriction structure, however the present invention is not limited thereto, and another method may be selected. For example, on the tunnel junction layer which is not patterned, the insulation film is formed and the insulation film is partially removed, whereby the second current constriction structure is formed. Other examples will be described in later mentioned examples.

In a case where an etching stop layer is needed in the patterning of the tunnel junction layer 142, the etching stop layer may be formed between the second DBR 104 and the tunnel junction layer 142. The optical film thickness of the etching stop layer is set to be an integral multiple of λc/2.

The n-type transparent conductive film 162 is disposed on the tunnel junction layer 142, the second DBR 104 and the insulation film 161. The carriers supplied from the upper ring electrode 150 are supplied to the patterned tunnel junction layer 142 via the transparent conductive film 162, as indicated by the dotted line in FIG. 1.

The transparent conductive film 162 is an n-type, and current normally does not flow from the n-type to the p-type, hence the carriers supplied from the upper ring electrode 150 flow as described above, even if an insulation film or the like does not exist between the transparent conductive film 162 and the upper DBR 104. In other words, the width d2 of the tunnel junction layer 142 becomes the width of the second current constriction structure.

Whereas the transparent conductive film is used as a path from the upper ring electrode 150 to the tunnel junction layer 142 in FIG. 1, the present invention is not limited thereto, and other configurations may be used if the path can supply the carriers in the same manner. Other examples will be described in the later mentioned examples.

In FIG. 1, the transparent conductive film 162 is one layer, but when necessary one or a plurality of layers of the transparent conductive film (e.g. SiOx, SiNx, TiOx) may be stacked thereon. In this case, the insulation film under the upper ring electrode 150 is partially removed, so that the upper ring electrode 150 and the transparent conductive film 162 are electrically connected.

The tunnel junction layer, where the p-type semiconductor layer and the n-type semiconductor layer having high carrier densities are joined like this, is a tunnel diode, hence by the tunnel effect, current also flows in the opposite direction via a thin depletion layer which is generated on the p-n junction interface. Therefore if voltage is applied between the ring electrode 150 and the lower electrode 151 so that the ring electrode 150 becomes positive, current flows from the ring electrode 150 to the second DBR 104 via the transparent conductive film 162 and the tunnel junction layer 142. The current that flows into the second DBR 104 diffuses inside the second DBR 104, and the current density distribution of the current injected into the active layer becomes the current density distribution, of which center is high and protruded.

Therefore according to the present embodiment, the far field image can be controlled. Further, by spreading the current density, which was concentrated to the peripheral portion of the oxidation constriction diameter, to the center portion, generation of the non-light emission recoupling or the like that spreads from the peripheral portion is restrained, hence durability of the element improves.

More details on the above will be described with reference to calculation examples.

The width d2 of the tunnel junction layer 142, that is, the width d2 of the second current constriction is smaller than the width d1 of the semiconductor portion on the inner side of the oxidation constriction layer 106, which is the first current constriction (this semiconductor portion is a portion where the current can flow, and is therefore called the “non-oxidized portion” herein below). In other words, d1 and d2 satisfy the following formula (1).

d2<d1 (1)

Here the case where the shapes of the non-oxidized portion (semiconductor portion on the inner side of the oxidation constriction layer 106) and the second current constriction (tunnel junction layer 142) are circles will be described below, but the shape is not limited to a circle, but may be an ellipse, a polygon or a shape similar thereto. In this case, each width d1 and d2, when sectioned at a certain cross-section, satisfies formula (1). If the shape includes an acute angle portion, current tends to concentrate to this portion, which is not desirable in terms of the current profile and durability, therefore the shape is preferably a shape close to a circle.

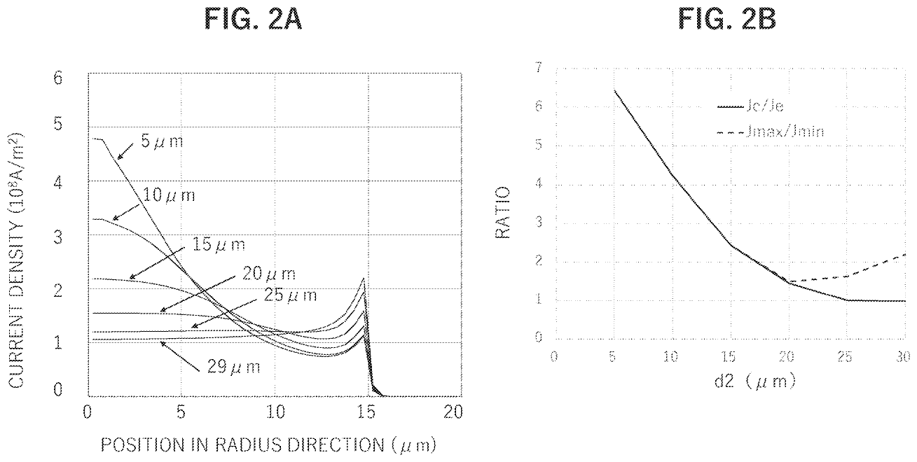

The effect of the above configuration will be described based on the calculation result indicated in FIG. 2A. The element configuration used for this calculation model is based on the configuration of Example 1, which will be described later.

FIG. 2A indicates a distribution of a current density that flows into the quantum well layer 140 in the case where the diameter d2 of the second current constriction changes from 5 μm to 29 μm when the oxidation constriction diameter d1 is 30 μm. The abscissa of FIG. 2A indicates a position in the radius direction where the center of the mesa (that is, the center of the non-oxidized portion) is position 0.

The solid line of FIG. 2B indicates the state of change when the current density in the center portion is Jc, and the minimum value of the current density in the peripheral portion (10 μm portion from the peripheral edge of d1 toward the center portion) is Je.

The far field image can be controlled by controlling the current density distribution of the current flowing into the quantum well layer to be higher in the center portion compared with the peripheral portion. In other words,

JC>Je (2)

is preferable.

Further,

Jc>2×Je (3)

is even more preferable.

According to FIGS. 2A and 2B, the current density distribution, of which center portion protrudes in a range where the diameter d2 of the second constriction portion is smaller than 25 μm, that is, in a range where formula (2) is satisfied, can be formed. Further, the current density profile protrudes even more in the center portion in a range where d2 is smaller than 15 μm, that is, in a range where formula (3) is satisfied.

Here if the current density that concentrates in the peripheral portion of the oxidation constriction diameter is expanded to the center portion, generation of non-light emission recoupling and the like, that spreads from the peripheral portion, is restrained, hence durability of the element improves. The dotted line in FIG. 2B indicates the state of change of Jmax/Jmin in the current density in the non-oxidized portion, where Jmax is the maximum value and Jmin is the minimum value. In a range where d2 is smaller than 20 μm, Jmax/Jmin (dotted line) is approximately the same as Jc/Je (solid line).

In terms of durability, it is preferable to satisfy

Jmax<3.3×Jmin (4)

Durability (life duration) in general is inversely proportional to the square of the current density, hence by satisfying the condition of formula (4), the in-plane dispersion of the local durability in the non-oxidized portion can be confined to within one digit.

If focus is placed on the far field profile rather than durability, then

Jmax<10×Jmin (5)

may be used. By satisfying the conditions of formula (5), the dispersion of the local durability in the non-oxidized portion can be confined to within two digits.

The three elements of the preferable device configuration, the non-oxidation constriction diameter d1 and the diameter d2 of the second current constriction portion mutually influence each other, and are determined in accordance with the application or requirement. For example, in a case where the device configuration illustrated in FIG. 1, has a 30 μm non-oxidation constriction diameter d1, as indicated in the later mentioned Example 1, a preferable value of the diameter d2 of the second current constriction portion is 12 to 18 μm if focus is placed on durability. The value of the diameter d2 may be 12 μm or less for applications where the focus is on the far field profile rather than on durability. The thickness t of the tunnel junction layer 142 is not especially limited, but may be in a range of at least 10 nm and not greater than 440 nm.

If the device configuration changes, appropriate ranges of d1 and d2 also change accordingly, so the preferable ranges thereof are selected depending on the application.

In the present invention, the second current constriction width is specified using the tunnel effect, and it is important for the tunnel effect to control several nm of the junction interface state. Compared with a configuration in which a film, of which doping density is at least the 19^{th} power, is formed in a process instead of using epitaxial growth for at least one layer, the reproducibility of the device and the yield thereof can be improved by forming the film by epitaxial growth, as in the present embodiment, with good controllability and reproducibility.

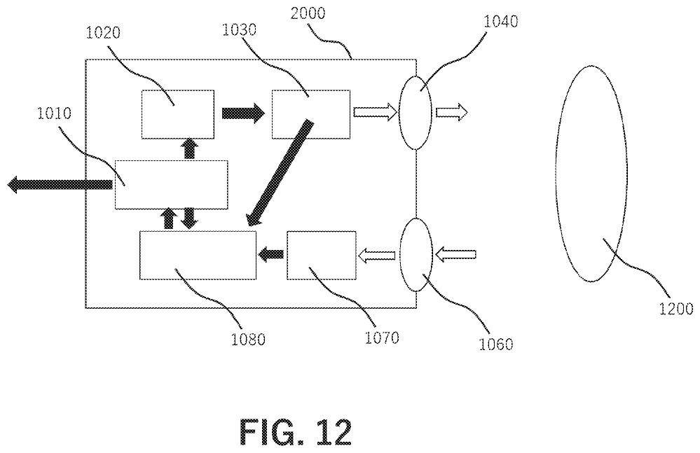

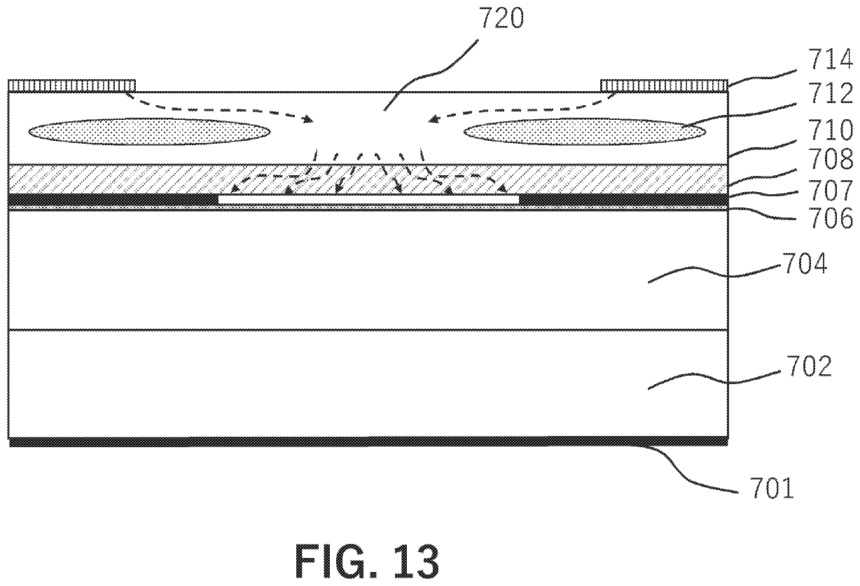

The second constriction structure is formed by disposing a relatively thin tunnel junction portion 142 and the transparent conductive film 162 on the second DBR 104. Further, a transparent conductive film of which conductivity of the material is higher than the p-GaAs layer used in FIG. 12, or the n-type GaAs layer described later mentioned examples, can be used. As a result, compared with the case of using the ion implantation method, the voltage increase in the second constriction structure can be reduced by about one digit in the entire VCSEL 100. Therefore by using the element of the present embodiment as a light source, a ranging device, which not only improves the ranging accuracy and the measurable distance, but also implements a smaller size and a lighter weight, can be provided.

Now examples of the present invention will be described in more detail with reference to the concrete layer configuration and the like of the light-emitting element.

### Example 1

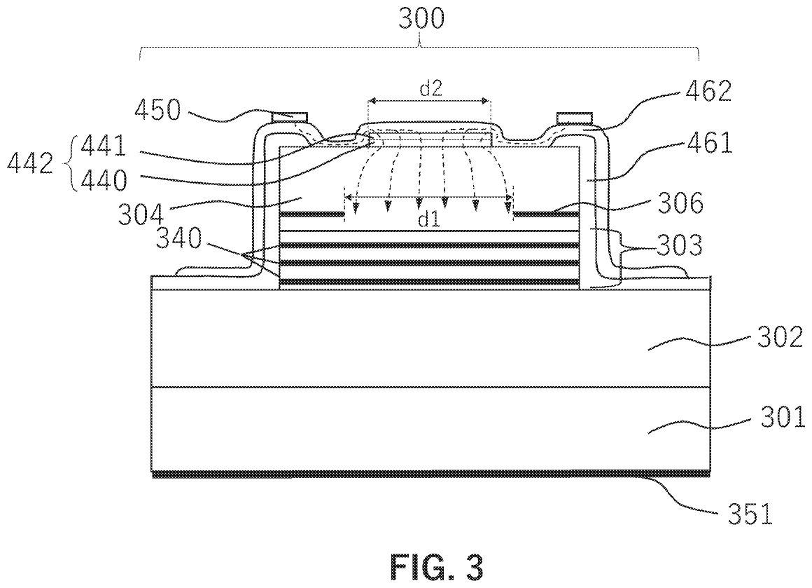

A VCSEL 300 according to Example 1 will be described with reference to FIG. 3. FIG. 3 is a cross-sectional view of the VCSEL 300 of Example 1. The VCSEL 300 is configured by a GaAs substrate 301, a first DBR 302, a semiconductor resonator cavity 303, and a second DBR 304, which are stacked in this sequence. In FIG. 3, these members are directly in contact with each other, but another member may be disposed there between. The above description is for describing the structure and is not intended to limit the sequence of manufacturing each member.

Three quantum well layers 340 are disposed in the resonator cavity 303. An Al_{0.98}GaAs is oxidized in a part of the second DBR 304 by steam oxidation, whereby an oxidation constriction layer 306, of which periphery has insulation properties, is formed. The oxidation constriction layer 306 corresponds to the first current constriction portion.

The resonator cavity 303 and the second DBR 304 are processed to be tubular mesa-shaped. A tunnel junction layer 442 is disposed on the second DBR 304. As illustrated in FIG. 3, out of the outermost surface of the second DBR 304, the tunnel junction layer 442 is disposed only in the portion of the diameter d2, including the mesa center. The diameter d2 is smaller than the diameter d1 of the non-oxidized portion of the oxidation constriction (first constriction structure). Then an indium tin oxide (ITO) layer 462 is formed on a portion where the tunnel junction layer 442 is not disposed on the upper face of the tunnel junction layer 442 and the upper face of the second DBR 304.

The ITO layer 462 is formed on the tunnel junction layer 442 and portions of the second DBR 304 where the tunnel junction layer 442 is not disposed, and electrically connects an upper ring electrode 450 and the tunnel junction layer 442. The optical thickness of the ITO layer 462 can be any integral multiple of λc/2, but λc/2 is preferable if conductivity in the horizontal direction of the substrate has no problem, since even the ITO layer somewhat absorbs light.

The tunnel junction layer 442 is circular-shaped, and the upper ring electrode 450 is electrically in contact with a part of the ITO layer 462. A lower common electrode 351 is in ohmic contact with the rear face of the GaAs substrate 301.

When the Al_{0.1}GaAs layer and the Al_{0.9}GaAs layer, of which both optical thicknesses are λc/4, form a pair, the first DBR 302 is configured with 35 pairs that are stacked. λc is a central wavelength of the high reflection band of the first DBR 302, and is 940 nm in Example 1.

The quantum well layer 340 has a configuration where an 8 nm thick In_{0.1}GaAs layer is sandwiched by 10 nm thick Al_{0.1}GaAs barrier layers. In Example 1, three quantum well layers are disposed in the resonator cavity 303.

When an Al_{0.1}GaAs layer and an Al_{0.9}GaAs layer, of which optical thicknesses are both λc/4, form a pair, the second DBR 304 is configured with 20 pairs that are stacked. A part of the Al_{0.1}GaAs layer closest to the quantum well layer 340 of the second DBR, however, is replaced with a 30 nm thick Al_{0.98}GaAs layer. After the mesa of the VCSEL 300 is formed, this Al_{0.98}GaAs layer is oxidized from the side wall of the mesa for a predetermined length from the edge of the mesa by steam oxidation, whereby the oxidation constriction layer 306 having insulation properties is formed on the periphery thereof.

The tunnel junction layer 442 is configured with at least two layers, that is, a p-type GaAs layer 440 which has been doped to a carrier density of 5×10¹⁹ cm⁻³, and an n-type GaAs layer 441 which has been doped to a carrier density of 1×10¹⁹ cm⁻³ sequentially from the substrate side. The total optical film thickness of these two layers is set to an integral multiple of λc/2. For example, the actual thickness of the n-type GaAs layer 441 is set to 190 nm.

In the case where absorption in a high doped p-type GaAs layer is a problem, the p-type GaAs layer 440 may be configured with a plurality of layers. For example, a two-layer configuration configured with: a layer on the substrate side which is doped to a carrier density of 1×10¹⁸ cm⁻³; and a layer thereon (layer in contact with the n-type GaAs layer 441) which is a thin layer (e.g. 20 nm thickness) doped to a carrier density of 1×10¹⁹ cm⁻³, may be used.

In a case where an etching stop layer is needed in the patterning of the tunnel junction layer 442, the etching stop layer may be formed between the second DBR 304 and the tunnel junction layer 442. The optical film thickness of the etching stop layer is set to be an integral multiple of λc/2.

The tunnel junction layer, where the p-type semiconductor layer and the n-type semiconductor layer, of which carrier densities exceed 1×10¹⁸ cm⁻³ are joined like this, is a tunnel diode, hence by the tunnel effect, current also flows in the opposite direction via a thin depletion layer which is generated on the p-n junction interface. Therefore if voltage is applied between the ring electrode 450 and the rear face electrode 351, so that the ring electrode 450 becomes positive, current flows from the ring electrode 450 to the second DBR 304 via the ITO layer 462 and the tunnel junction layer 442. The current that flows into the second DBR 304 diffuses inside the second DBR 304, and the current density distribution of the current injected into the active layer becomes the current density distribution of which center is high and protruded.

Since the current density distribution of which center is high and protruded can be implemented as described above, the far field image can be controlled. Further, by spreading the current density, which concentrated to the peripheral portion of the oxidation constriction diameter, to the center portion, generation of the non-light emission recoupling or the like that spreads from the peripheral portion is restrained, hence durability of the element improves.

In Example 1, the diameter d2 of the tunnel junction layer 442 is 10 μm, and the diameter d1 of the semiconductor portion (that is, a portion through which current can flow, the non-oxidized portion) on the inner side of the oxidation constriction layer 306 is 30 μm. Since the non-oxidized portion is the portion of the resonator cavity 303 through which current can flow, the diameter of the non-oxidized portion is the light-emitting diameter of the VCSEL. This aspect of Example 1 is the same in Example 2 and in later examples.

In Example 1, as indicated in FIGS. 2A and 2B, the profile of the current density distribution of the current that flows into the quantum well layer 340 can be formed to protrude in the center portion, whereby the far field image can be controlled. In the configuration of Example 1, the values of Jc/Je and Jmax/Jmin are 4.2. In Example 1, a value greater than 3.3 is selected for the value of Jmax/Jmin, since short term use is assumed. In the case of placing focus on life duration characteristics, on the other hand, d2 may be set to 15 μm, for example. In this case, the values of Jc/Je and Jmax/Jmin become 2.4.

Further, the second constriction structure is formed by forming the thin transparent conductive film 462 and the tunnel junction layer 442 on the second DBR 304. Further, the tunnel junction layer is a high doped layer, in which carrier densities of the p-type semiconductor layer and the n-type semiconductor layer are both in the 10¹⁹ order, and is low resistance. Therefore the voltage increase in the second constriction structure can be reduced by about one digit compared with the ion implantation method, since the material constituting the current path has low conductivity and is thin. By using the element of Example 1 as the light source, a ranging device, which not only improves the ranging accuracy and the measurable distance, but also implements a smaller size and a lighter weight, can be provided.

### Example 2

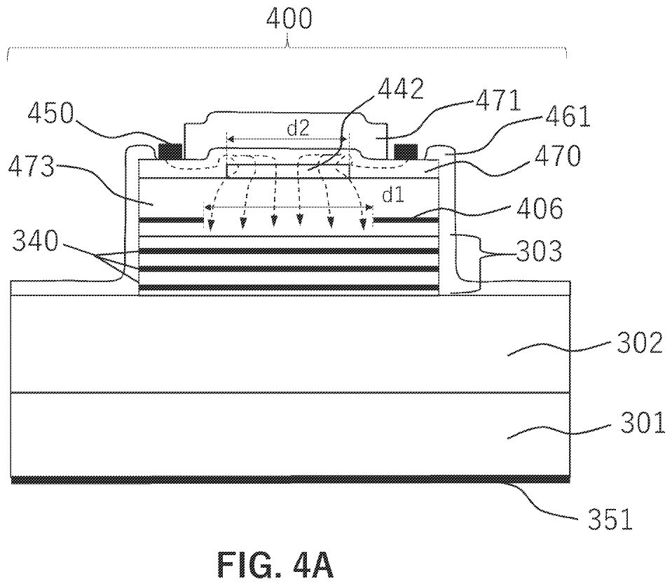

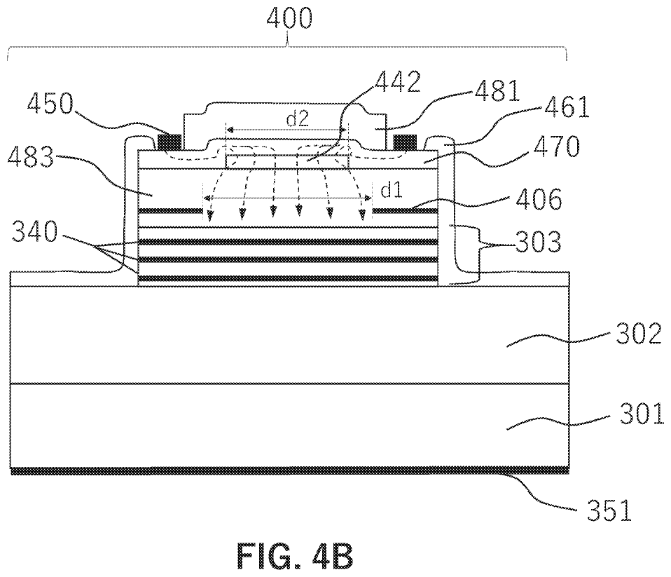

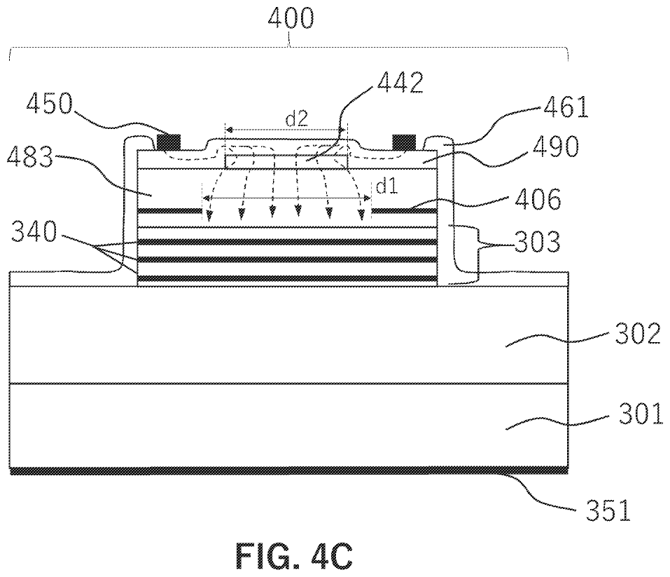

A VCSEL 400 according to Example 2 will be described with reference to FIG. 4A. FIG. 4A is a cross-sectional view of the VCSEL 400. The configuration of the portion from the rear face electrode 351 to the resonator cavity 303 in the VCSEL 400 is the same as Example 1, hence these composing elements are denoted with a same reference numbers as Example 1 respectively, and description thereof is omitted.

A major difference of Example 2 from Example 1 is that a p-type semiconductor layer 473, that includes an oxidation constriction portion 406, exists on the resonator cavity 303, and the tunnel junction layer 442 is disposed on a part of the upper face of the p-type semiconductor layer 473. On the upper face of the tunnel junction layer 442 and the p-type semiconductor layer 473, an n-type GaAs layer 470 is disposed on the part of the upper face where the tunnel junction layer 442 does not exist. The n-type GaAs layer 470 is formed by growing crystals up to the layer to be the tunnel junction layer 442 first, then processing the tunnel junction layer 442 in a predetermined shape, and growing crystals again to be the n-type GaAs layer 470. On the n-type GaAs layer 470, the upper ring electrode 450 and a dielectric DBR 471 are disposed.

In Example 1, the size of d2 is 10 μm or 15 μm. In some cases, it may be difficult to set d2 to 15 μm or less due to process restrictions or the like. In Example 2, in order to increase the values of Jc/Je and Jmax/Jmin in such a case, the distance between the quantum well layer 340 and the tunnel junction layer 442, which is the second constriction structure, is set to be shorter than the distance which was set in Example 1, that is, set to be thinner than the second DBR thickness. Then the reflectance reduced thereby is compensated for by disposing the third DBR 471.

Specifically, when the thickness of the p-type semiconductor layer 473 is ⅗ of the second DBR of Example 1, 4.4 can be acquired as the value for both Jc/Je and Jmax/Jmin, even if d2 is 15 μm.

The size of the third DBR 471 in the horizontal direction of FIG. 4A must be sufficiently large optically as a resonator above the active layer. In FIG. 4A, the size of the third DBR 471 is smaller than the inner diameter of the upper ring electrode 450 and is larger than d1, but the present invention is not limited thereto. The size of the third DBR 471 may be about the same or larger than the inner diameter of the upper ring electrode 450, as long as current can be supplied to the upper ring electrode 450 in this configuration.

The p-type semiconductor layer 473 is configured with Al_{0.1}GaAs, and a 30 nm thick Al_{0.98}GaAs layer is disposed on a part thereof. The periphery of the Al_{0.98}GaAs layer is oxidized by steam oxidation in the middle of the wafer processing after the crystal growth, whereby the oxidation constriction layer 406 is formed.

The tunnel junction layer 442 is configured with a p-type GaAs layer which has been doped to a carrier density of 5×10¹⁹ cm⁻³, and an n-type GaAs layer which has been doped to a carrier density of 1×10¹⁹ cm⁻³.

The dielectric DBR 471 has a structure where SiO₂ and TiO₂ are alternately layered, and the optical film thicknesses thereof are λc/4 respectively. A number of pairs is appropriately adjusted so as to acquire a reflectance equivalent to the second DBR of Example 1.

FIG. 4B is a modification of Example 2. In the above example, the tunnel junction layer 442 is disposed on the p-type semiconductor layer 473, but the present invention is not limited thereto. As illustrated in FIG. 4B, a second DBR 483 configured with a p-type semiconductor layer may be disposed on the resonator cavity 303, instead of the p-type semiconductor layer 473, and the tunnel junction layer 442 may be disposed thereon. The entire thickness of the second DBR 483 is a thickness of about ⅔ the second DBR 304 of Example 1.

In Example 2, an oxidized layer is disposed inside the second DBR 483, so as to form a partially oxidized oxidation constriction layer 406 in the periphery thereof. The tunnel junction layer 442 is disposed on the upper DBR 483, and the n-type GaAs layer 470 is formed by patterning the tunnel junction layer 442 in the same manner as described above. On the n-type GaAs layer 470, a third DBR 481, which is formed of a dielectric or a semiconductor having a reflectance of about ⅓ the upper DBR 304 of Example 1, is disposed. The DBR 481 has a layered structure where a high refractive layer and a low refractive layer, of which optical film thicknesses are both λc/4, are stacked a plurality of times.

By this configuration, the distance of the high doped tunnel junction layer from the active layer in the resonator cavity can be increased even more than FIG. 4A, hence loss during resonance can be decreased.

FIG. 4C is another modification of Example 2. In FIG. 4C, a fourth DBR 490, formed of an n-type semiconductor, is disposed on the second DBR 483 or the tunnel junction layer 442. It is only the upper ring electrode 450 that is disposed thereon. In this design, the upper DBR 483, formed of the p-type semiconductor and the DBR 490 formed of the n-type semiconductor, as a pair, play the role of the upper reflector of the resonator. In this modification as well, an effect similar to the above description can be acquired.

### Example 3

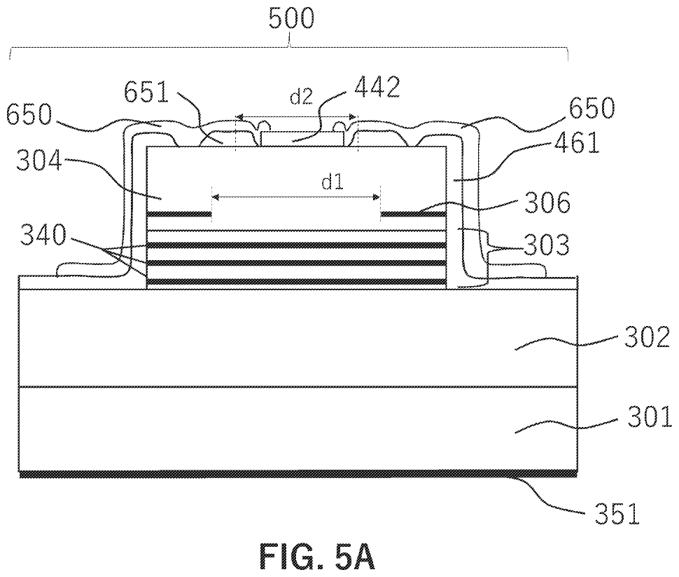

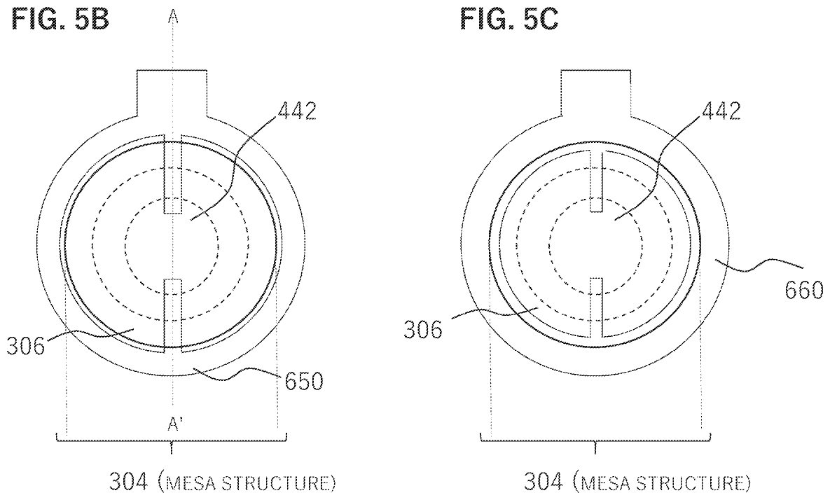

A VCSEL 500 according to Example 3 will be described with reference to FIG. 5A. FIG. 5A is a cross-sectional view of the VCSEL 500. In the VCSEL 500, the configuration of the portion from the lower common electrode 351 to the tunnel junction portion 442 is the same as Example 1, hence these composing elements are denoted with same reference numbers respectively, and description thereof is omitted.

A major difference of Example 3 from Example 1 is that a wiring electrode 650 is disposed on the second DBR 304. The wiring electrode 650 is not a transparent electrode but a metal electrode, and is opaque to the light-emitting wavelength of the VCSEL 500.

FIG. 5B is a top view of the VCSEL 500 and depicts a shape of the wiring electrode 650. FIG. 5A is a cross-sectional view sectioned at A-A′ in FIG. 5B.

The wiring electrode 650 has a ring-shaped portion on the outer side of the mesa of the second DBR 304, and the electrode extends from this portion to the tunnel junction layer 442, which is disposed on the upper portion of the upper DBR 304. The wiring electrode 650 is in ohmic contact with the tunnel junction layer 442. In other words, the wiring electrode 650 is formed of a material that is in ohmic contact with the high doped n-type GaAs layer. Specifically, the wiring electrode 650 has a two-layer configuration, that is, AuGe is at the lowest layer, and Au is formed thereon. Another insulation film 651, which is different from the insulation film 461, is formed under the wiring electrode 650. The functions of the insulation film 651 will be described later.

The thickness of the wiring electrode 650 (upper portion of the mesa) is 3 μm in Example 3. In the VCSEL processing steps, a mask is formed first by a lift off method or by photolithography, then a region where the mask is not formed is removed by etching, whereby the wiring electrode 650 is formed. The minimum width of this forming process is typically about 3 μm or 5 μm. This processing dimension is considerably different from the processing dimension in the process of silicon devices, because in VCSEL, the step difference between the mesa portion and the peripheral portion thereof is large, and it is difficult to focus on both the upper and lower region of the step difference during exposure in photolithography, for example. Therefore in Example 3 as well, 3 μm is used in terms of minimizing the width in a practically mass producible range.

In the wiring electrode 650, the portion contacting the upper face of the tunnel junction layer 442 has a width of 3 μm and a length of 3 μm. The diameter d1 of the opening of the oxidation constriction layer 306 is 30 μm (radius 15 μm), and the diameter d2 of the tunnel junction layer 442 is 15 μm (radius: 7.5 μm). This means that a 10.5 μm long and 3 μm wide portion is overlapped with a portion of the wiring electrode 650 and the light-emitting region (opening of the oxidation constriction layer 306) in the planar view.

In Example 3, the opaque wiring electrode 650 is disposed on the second DBR 304, therefore a light emitted directly below the wiring electrode 650 is partially shielded. This is a disadvantage of Example 3 since light extraction efficiency drops. In Example 3, 8.9% of the entire area of the light-emitting portion is covered by the electrode 650.

A material of a transparent electrode, such as ITO, also depends on the thickness and a film disposition method, but in many cases 10% or more of light absorption often occurs therein when the typical thickness is 100 nm at a 940 nm wavelength. In the configuration of Example 3, the ratio of the area shielded by the wiring electrode 650 is 8.9%, hence compared with the configuration where the upper face of the VCSEL is covered with the ITO film, an equivalent light extraction efficiency can be implemented.

In Example 3, an insulation film 651 is disposed under the wiring electrode 650 in order to reduce the influence of a drop in the light extraction efficiency due to the light shielding by the wiring electrode 650. The insulation film 651 is 162 nm thick SiO₂. The thickness of the insulation film 651 is an optical film thickness, that is, the ¼ the oscillation wavelength of the VCSEL 500. On the insulation film 651, the wiring electrode 650, which is formed of metal, is disposed, and the reflectance viewed from the resonator cavity 303 side drops enough for the VCSEL 500 to interrupt oscillation. Example 3 is designed such that the phase of the light reflected from the insulation film 651 and the wiring electrode 650 shifts from the phase of the light reflected by the DBR 304 by π, so that the reflectance decreases compared with the reflectance by the DBR 304 alone.

By decreasing the reflectance of the portion shielded like this so as to interrupt the laser oscillation of the VCSEL 500, the influence of a drop in the light extraction efficiency caused by the shield of the wiring electrode 650 is reduced in Example 3. The specific content of this will be described below.

If laser oscillation is interrupted by disposing the wiring electrode 650 and the insulation film 651, as mentioned above, in the portion shielded by the wiring electrode 650, the laser oscillation, that is, the recoupling of carriers due to induced emission, no longer occurs in this portion. Therefore in the active layer directly under the wiring electrode 650, the carrier density becomes higher than a peripheral area where the induced emission continues and the recoupling rate of the carriers is high. As a result, the carriers diffuse to the peripheral area due to the difference in carrier density, and change into photons because of the recoupling by induced emission in the peripheral area. The photons generated in the peripheral area are not shielded by the wiring electrode 650, and can be extracted out of the VCSEL 500, hence the disadvantage of the drop in light extraction efficiency, due to the light shielding by the wiring electrode 650, can be reduced.

In the configuration in FIG. 5A, the insulation film 651 is separated from the insulation film 461, but the insulation film 461 may be covered by the insulation film 651. The insulation film 461, which plays a role of performing passivation of the side wall of the mesa, may be integrally formed with the insulation film 651 if these insulation films 461 and 651 can be formed at a same film thickness.

In FIG. 5B, the wiring electrode 650 extends in two directions from the periphery of the mesa to the tunnel junction layer 442, but the present invention is not limited thereto. It is sufficient if the wiring electrode 650 extends at least in one direction. In the case where a plurality of wiring electrodes 650 are extended, the intervals thereof should be as large as possible. For example, if the number of wiring electrodes 650 is 2, the intervals thereof are 180°, and if the number of wiring electrodes 650 is 3, the intervals thereof are 120°.

In the configuration of Example 3, the insulator is under the shielding portion in order to reduce the reflectance of the shielded portion, but the present invention is not limited thereto, and other configurations, such as partially removing the upper portion of the upper DBR 304, may be used, as long as the reflectance of the shielded portion can be reduced.

FIG. 5C is a modification of Example 3. In this modification, the wiring electrode 660 covers the entire periphery of the mesa, and is also disposed on the peripheral edge of the upper portion of the mesa. In this case, more area of the metal covers the step difference of the mesa, and the entire periphery of the mesa is covered by the metal, hence the risk of metal disconnection can be reduced. Further, by performing exposure of photolithography focusing on the upper portion of the mesa, the wiring electrode can be connected with the tunnel junction portion 442 using thinner wiring than the wiring disposed on the light-emitting portion. As a consequence, the ratio of the portion shielded by the wiring electrode 660 can be decreased.

In Example 3, in the case where the degree of the diffusion of the carriers in the horizontal direction in the tunnel junction portion 442 is increased after current is supplied from the wiring electrodes 650 and 660 to the tunnel junction portion 442, the film thickness of the n-type high doped layer can be thick enough not to cause a light absorption problem. In this case, an increase in the film thickness of the n-type high doped layer is set to be an integral multiple of λc/2. In other words, the entire tunnel junction portion is set to be an integral multiple of λc/2. Specifically, in the case where kc is 940 nm, the thickness of the n-type high doped layer is increased by 132 nm, so that the total thickness of the n-type high doped layer is set to 222 nm, and the thickness of the entire tunnel junction layer 442, including the p-type semiconductor, is set to about 400 nm.

Even in this configuration, the layer on the second DBR 304, when forming the second current constriction structure, becomes the tunnel junction layer 442 of a maximum of about 440 nm, even if a general film deposition accuracy of ±10% is considered. In the tunnel junction layer, both the p-type semiconductor layer and the n-type semiconductor layer are high doped layers, of which carrier density is in the 10¹⁹ order, hence the voltage increase in the second current constriction structure portion, with respect to the entire VCSEL 500, can be reduced by about one digit, compared with the ion implantation method. As a consequence, by using this element for the light source, a ranging device, which not only improves ranging accuracy and the measurable distance but also implements a smaller size and a lighter weight, can be provided.

### Example 4

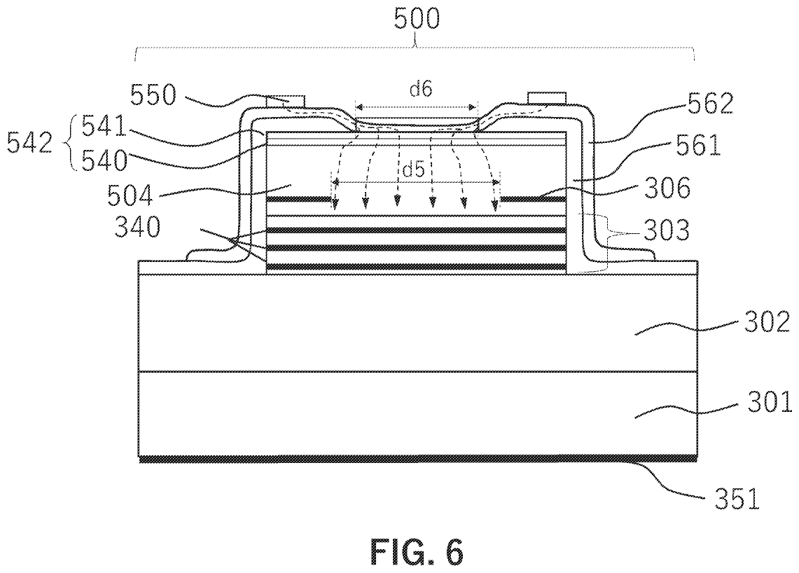

A VCSEL 500 according to Example 4 will be described with reference to FIG. 6. FIG. 6 is a cross-sectional view of the VCSEL 500. The VCSEL 500 is configured by the GaAs substrate 301, the first DBR 302, the semiconductor resonator cavity 303, a second DBR 504 and a tunnel junction layer 542, which are stacked in this sequence.

The resonator cavity 303, the second DBR 504 and the tunnel junction layer 542 are processed to be tubular mesa-shaped, and are covered with an insulation layer 561. An ITO layer 562 is formed on the insulation layer 561. The optical film thickness of the ITO layer 562 is λc/2.

As illustrated in FIG. 6, the insulation layer 561, of which center portion is partially removed, is formed on the upper face of the tunnel junction layer 542, which has been processed to have a mesa shape. Hereafter the portion where the insulation layer 561 is removed is called the “insulation opening”. In the insulation opening, the ITO layer 562 is in contact with the upper face of the tunnel junction layer 542. The shape of the insulation opening is a circle in Example 4. In Example 4, carriers are supplied from the insulation opening portion via the tunnel junction layer 542. This means that the second current constriction portion is configured with the ITO layer 562, the insulation layer 561 having the insulation opening, and the tunnel junction layer 542. The upper ring electrode 550 is electrically in contact with a part of the ITO layer 562. The lower common electrode 351 is in ohmic contact with the rear face of the GaAs substrate 501.

The tunnel junction layer 542 is configured with a p-type GaAs layer 540 which has been doped to a carrier density of 5×10¹⁹ cm⁻³, and a n-type GaAs layer 541 which has been doped to a carrier density of 1×10¹⁹ cm⁻³. The tunnel junction layer, where the p-type semiconductor layer and the n-type semiconductor layer, of which carrier densities both exceed 1×10¹⁸ cm⁻³ are joined like this, is a tunnel diode. Hence by the tunnel effect, current also flows in the opposite direction via a thin depletion layer which is generated on the p-n junction interface by the tunnel effect, just like the case of the tunnel junction layer 442 of Examples 1 and 2.

In the case where the cross-sectional shape of the insulation layer 561 is tapered as the width decreases in the direction to the center portion as illustrated in FIG. 6, the size of the second constriction structure can be defined by the distance d6 between the tip portions of the insulation layer 561. In other words, d6 is the real size where current is constricted by the second constriction structure.

In Example 4, the tunnel junction layer 542, which is not patterned, exists on the entire surface of the mesa, hence the preferable diameter d6 of the insulation opening and the preferable diameter d5 of the non-oxidized portion are different from Examples 1 and 2. The effect will be described below.

In Example 4, the diameter d6 of the insulation opening portion where the insulation layer 561 is removed is 20 μm, and the diameter d5 of the non-oxidized portion on the inner side of the oxidation constriction layer 506 is 70 μm.

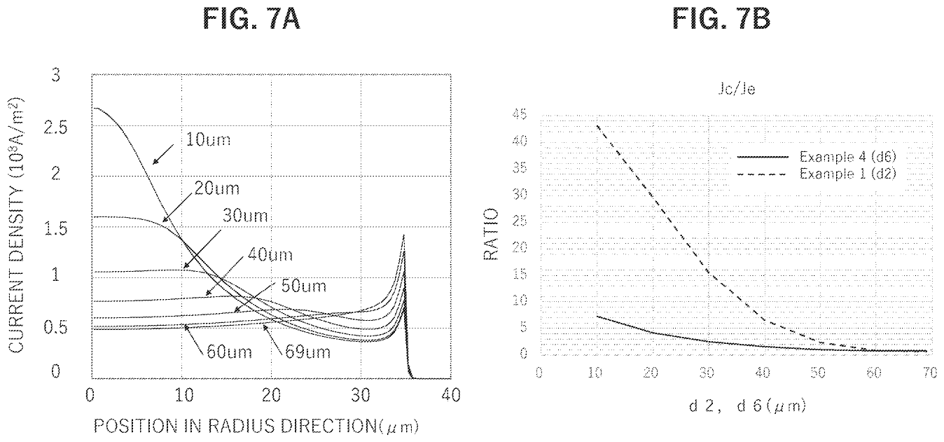

The effect of this configuration will be described based on the calculation result indicated in FIG. 7A. In FIG. 7A, the abscissa indicates a position in the non-oxidized portion in the radius direction, and the ordinate indicates a current density, and the values in the graph indicate each value of the diameter d6 of the insulation opening portion. FIG. 7A indicates a distribution of the current density when d5 is fixed to 70 μm, and d6 is changed in the range of 10 μm to 69 μm. As indicated in FIG. 7A, the current density distribution maintains the profile of which center protrudes, if d6 is up to 30 μm. In this case, current can be injected into the boundary of the oxidized portion and the non-oxidized portion, that is, the position of 35 μm on the abscissa in FIG. 7A.

The solid line in FIG. 7B indicates the ratio of Jc/Je in the case where d5 is fixed to 70 μm and d6 is changed. As indicated in FIG. 7B, formula (3) is satisfied when d6 is smaller than about 35 μm.

For comparison, the dotted line indicates the case of Example 1. The case of Example 1 is the case where d1 is 70 μm in the structure of Example 1. Jmax/Jmin is approximately the same as Jc/Je when d2 or d6 is 30 μm or more, hence it is not indicated here.

By the same calculation, a value of d2 or d6, that satisfies formula (3) and formula (5) simultaneously when d1 or d5 is an arbitrary value, can be determined. Table 1 indicates the value of d2 or d6 that satisfies formula (3) and formula (5) simultaneously when d1 or d5 is 30, 50, 70 and 100 μm.

TABLE 1

| | Example1 | Example3 |
|---|---|---|
| Diameter of the first | Diameter of the second | Diameter of the second |
| constriction portion | constriction portion | constriction portion |
| d1 or d5 (μm) | d2 (μm) | d5 (μm) |
| 30 | 13-17 | None |
| 50 | 30-36 | 10-19 |
| 70 | 40-52 | 25-35 |
| 100 | —(Uncalculated) | 50-59 |

As Table 1 indicates, in the case of Example 1, a minimum value of the preferable range of d2 is 4 μm when d1 is 30 to 70 μm, and the allowable range of d2 becomes the maximum (6 μm) when d1 is 50 μm. In Example 4, on the other hand, the preferable range of d6 is at least 9 μm when d5 is at least in the 50 to 100 μm range.

As described above, in Example 4, the tunnel junction layer 542 is disposed on the entire highest portion of the mesa, and the carriers spread in the direction parallel with the substrate, particularly by the n-type GaAs layer 541 in the tunnel junction layer 542. Therefore a desirable current density distribution can be implemented even if the light-emitting area is increased.

In the description of Example 4, the tunnel junction layer 542 is located on the upper side of the second DBR 504, but the tunnel junction layer may be disposed instead on the high refractive index layer which is the uppermost layer of the second DBR 504. In this case, the film thickness is set such that the optical film thickness of the tunnel junction layer becomes an odd multiple of λc/4. In the case of Example 4, carriers diffuse in the horizontal direction in the n-type GaAs layer 541, hence this film thickness need to be relatively thick. For example, this film thickness is set to 190 nm and the optical film thickness of the tunnel junction layer is set to 3λc/4.

Further, in Example 4, the tunnel junction layer 542 is formed on the entire upper surface of the second DBR 304, but the tunnel junction layer 542 need not be disposed at least in the peripheral portion of the mesa structure. For example, the tunnel junction layer 542 may be formed to have a diameter that includes the center of the mesa and is longer than d5, so as to include the entire non-oxidized portion of the oxidation constriction layer 306 in the planar view.

In Example 4, the diameter of the non-oxidized portion can be set larger than Example 1, hence a higher power light-emitting element can be implemented.

Here it may be possible to dispose the tunnel junction layer 542 between the resonator cavity 303 and the upper DBR. However in this configuration, the distance between the high doped tunnel junction layer and the active layer decreases more than Example 4, and loss increases during resonance, which is a disadvantage.

Specifically, it is assumed that absorption in the tunnel junction portion is 1%, for example. If the tunnel junction layer is disposed between the resonator cavity and the upper DBR in this case, and the light emitted from the active layer is assumed to be 100%, then 1% of this light is absorbed.

In standard VCSEL design, it is common that the reflectance of the upper DBR is set to about 99%. Therefore if the tunnel junction layer is disposed on the upper DBR, for example, and the light emitted from the upper DBR (light emitted from the active layer) is assumed to be 100%, then an additional 1% of the above mentioned 1% (that is, 0.01% of the light emitted from the active layer) is absorbed by the tunnel junction layer.

Generally the VCSEL stops oscillation if absorption increases by about 1%. Further, the upper DBR is an n-type, hence the current constricted by the insulation opening (upper second constriction structure) spreads too much in the horizontal direction, which makes it difficult to acquire a preferable current profile in the active layer. As a consequence, it is preferable that the tunnel junction layer is distant from the resonator cavity, as described in Example 4.

### Example 5

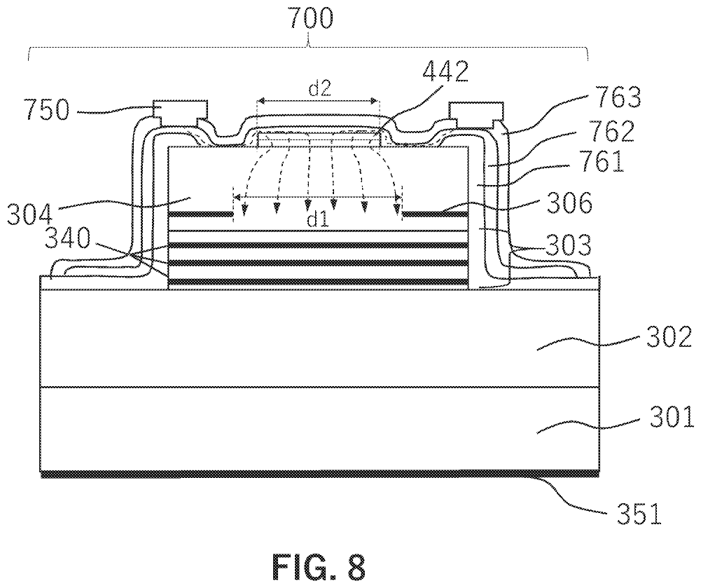

A VCSEL 700 according to Example 5 will be described with reference to FIG. 8. In Example 5, absorption of the light of the ITO layer is reduced by decreasing the film thickness of the ITO layer.

Example 5 will be described based on the above mentioned Example 1. A composing element the same as Example 1 is denoted with a same reference number, and description thereof is omitted.

If absorption by the ITO layer is high and this influences the oscillation and output of the VCSEL in Example 1, the film thickness of the ITO layer may be decreased to be thinner than λc/2, and a single transparent insulation layer or a plurality of layers may be disposed thereon, as Example 5.

In the VCSEL 700 described in Example 5, the tunnel junction layer 442 is formed at the center of the upper face of the second DBR 304, which has been processed to be a mesa shape, and an ITO layer 762 is disposed thereon. Here the film thickness of the ITO layer 762 is assumed to be 100 nm. Then a transparent insulation film layer 763 (e.g. SiOx) is formed thereon, so that the total optical film thickness of the ITO layer 762 and the transparent insulation film layer 763 becomes an integral multiple of λc/2. An upper ring electrode 750 is electrically connected with a part of the ITO layer 762 at a portion where the transparent insulation film layer 763 is partially removed.

In a case where deviation of the optical film thickness of the ITO layer 762 from λc/2 causes a drop in reflectance in the insulation opening and this drop becomes a problem, a plurality of transparent insulation film layers may be further formed on the transparent insulation film layer 763. The reflectance in the insulation opening can be improved by making the thickness of the transparent insulation film in contact with the ITO layer 762 to be λc/2 when added with the thickness of the ITO layer 762, then alternately stacking two types of layers having mutually different refractive indexes so that the optical film thickness becomes λc/4.

In the case of forming additional transparent insulation film on the transparent insulation film layer 763, an opening the same as that of the transparent insulation film layer 763 is formed on these transparent insulation film layers as well, so that the upper ring electrode 750 and the ITO layer 762 are electrically connected.

According to Example 5, in addition to the effect of Example 1, absorption by the ITO layer can be reduced, hence light-emitting efficiency can be further improved. Further, the risk of stopping oscillation due to a decrease in reflectance can be reduced.

Example 5 is based on Example 1, but the present invention is not limited thereto, and may be applicable to other examples.

In Example 5, the thickness of the ITO layer 762 is 100 nm, but the thickness of the ITO layer can be thinner as long as the increase in the resistance value from the upper ring electrode to the tunnel junction portion, caused by the electric conductivity, does not become a problem. Considering the probability of the disconnection that may be caused by a stop difference of the tunnel junction portion, however, the thickness of the ITO layer is preferably 10 nm or more.

### Example 6

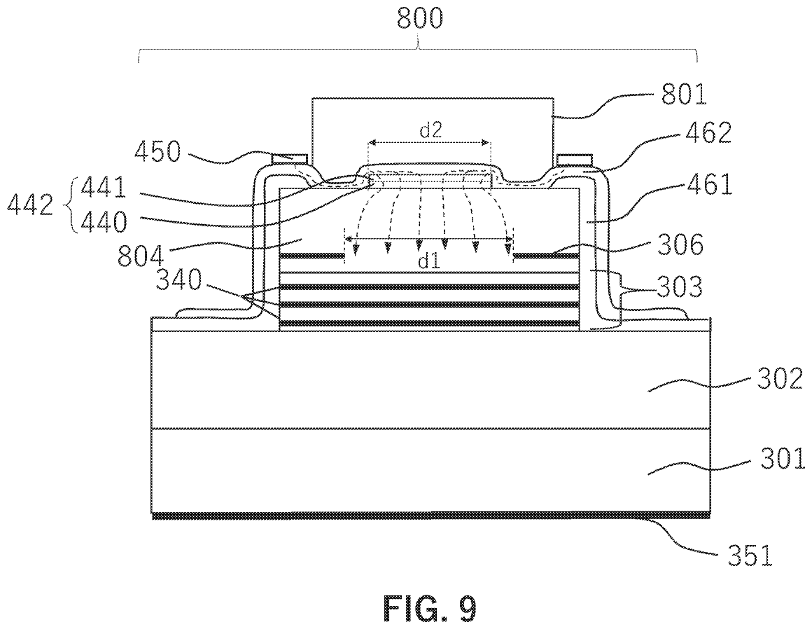

A VCSEL 800 according to Example 6 will be described with reference to FIG. 9. A difference from Example 1 is that the VCSEL 800 further includes a third DBR 801 on the ITO layer 462. The third DBR is configured with a dielectric, such as SiOx, SiNx and TiOx.

In Example 1, the size of d2 is 10 μm or 15 μm. In some cases, it may be difficult to set d2 to 15 μm or less due to process restrictions or the like. In Example 6, in order to increase the values of Jc/Je and Jmax/Jmin in such a case, the thickness of the second DBR 804 is set to be thinner than the thickness which was set in Example 1, and the reflectance reduced thereby is compensated by disposing the third DBR.

Specifically, when the thickness of the second DBR 804 is ⅗ of Example 1, 4.4 can be acquired as the set value of both Jc/Je and Jmax/Jmin, even if d2 is 15 μm.

The size of the third DBR 801 in the horizontal direction of FIG. 9 must be sufficiently large optically as a resonator above the active layer. In FIG. 9, the size of the third DBR 801 is smaller than the inner diameter of the upper ring electrode 450 and is larger than d1, but the present invention is not limited thereto. The size of the third DBR 801 may be about the same as or larger than the inner diameter of the upper ring electrode 450, as long as current can be supplied to the upper ring electrode 450 in this configuration.

In Example 6, the thickness of the second DBR 804 is set to be thinner than what was set in Example 1, but in order to acquire desirable current density distribution, the thickness of the second DBR 804 may be set to be thicker than that of Example 1. In this case, one layer or a plurality of layers of the second DBR may be set to 3λc/4, for example.

Example 6 is based on Example 1, but the present invention is not limited thereto, and may be applicable to Examples 3 to 5.

### Example 7

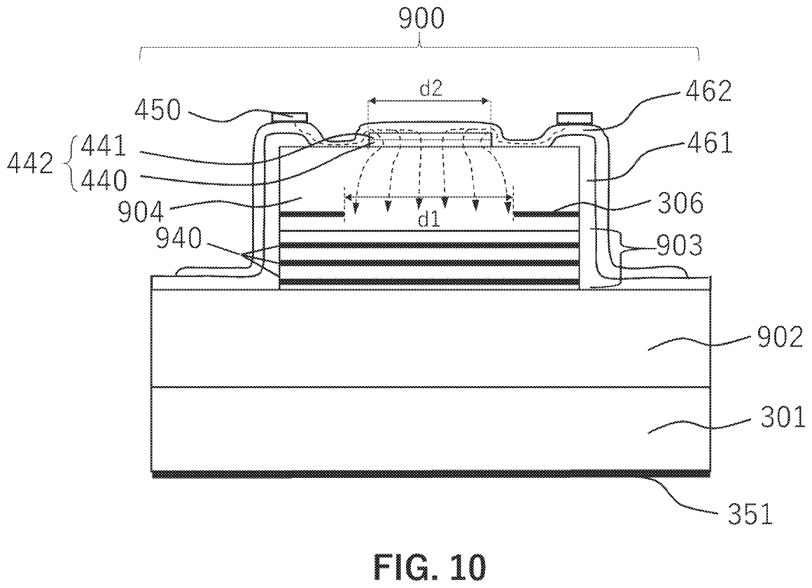

A VCSEL 900 according to Example 7 of the present invention will be described with reference to FIG. 10. A difference of the VCSEL 900 from Example 1 is that λc is 850 nm. Therefore in a first DBR 902 and a second DBR 904, the optical thickness of each layer is changed to be λc/4 (=212.5 nm). The composition and the optical film thicknesses of a quantum well layer 940 and a resonator cavity 903 are appropriately adjusted accordingly.

Specifically, the quantum well layer 940 is configured such that an 8 nm thick GaAs layer is sandwiched by 8 nm thick Al_{0.3}GaAs barrier layers. In Example 7, three quantum well layers are disposed in the resonator cavity 903.

Thereby even for an 850 nm band wavelength of which absorption rate in the substrate is high, and with which implementing high power is difficult in rear face emission, a high power semiconductor light-emitting element can be provided with restraining the influence of absorption by the substrate.

Example 7 has a configuration of Example 1 where the oscillation wavelength is changed, but can be applied to any of Examples 2 to 6 of the present invention.

### Example 8

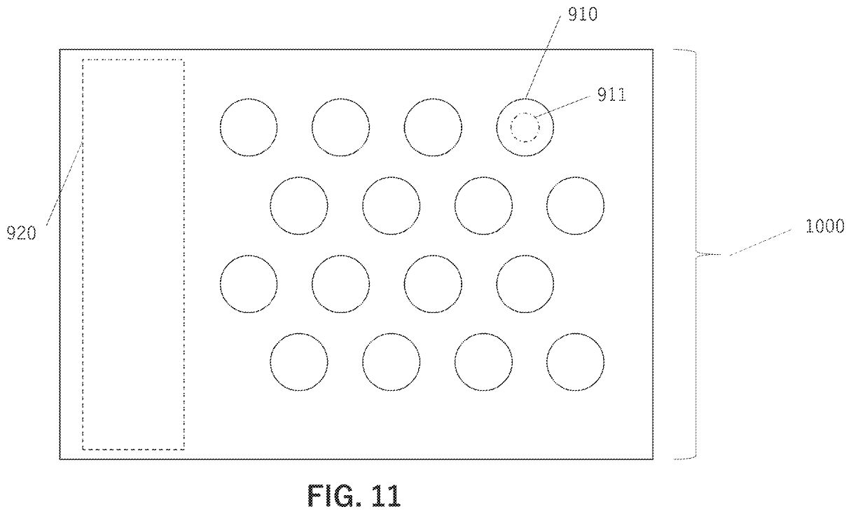

The VCSEL array 1000 according to Example 8 of the present invention will be described with reference to FIG. 11. In Examples 1 to 7, there is one VCSEL light-emitting portion, but the present invention is not limited to thereto, and a plurality of VCSEL light-emitting portions may be disposed.

As illustrated in FIG. 11, in the VCSEL array 1000 of Example 8, a plurality of VCSELs 300 described in Example 1 are disposed in an array. A circle 910 indicates an inner diameter of the upper ring electrode. A dashed line 911 indicates a light-emitting area, of which inner diameter is d1. A portion indicated by the dotted line is a pad portion 920 of the upper electrode.

As illustrated in FIG. 11, a plurality of light-emitting points are connected to a same electrode, and a plurality of light-emitting points emit light simultaneously. By using this configuration, the output from the light-emitting element can have even higher power.

In Example 8, 16 light-emitting points are arranged 4×4 in a triangular lattice, but the present invention is not limited thereto, and a number of light-emitting points and the arrangement of the light-emitting points may be changed to suit an application. In this example, the entire plurality of light-emitting points are simultaneously driven, but, depending on the application, the light-emitting points and the corresponding upper electrodes may be divided into a plurality of groups and driven, or individually driven so as to emit light at different timings.

Example 8 indicates a configuration in which the VCSEL of Example 1 is disposed in an array, but any VCSEL of Examples 2 to 7 may be disposed in an array. If the VCSEL according to Example 4 is disposed in an array, a larger diameter of the non-oxidized portion can be set than in the case of using the VCSEL according to Example 1 to 3, hence this array can implement higher power with a smaller area.

### Example 9

FIG. 12 indicates a ranging device 2000 according to Example 9. FIG. 12 is a laser light detection and ranging (LiDAR) device, in which the VCSEL of the above examples is used as a light source unit. As indicated in FIG. 12, the ranging device 2000 is configured with a general control unit 1010, a VCSEL driver 1020, a VCSEL 1030, a light-emitting side optical system 1040, a light-receiving side optical system 1060, a light-receiving image sensor 1070 and a distance data processing unit 1080.

In Example 9, the VCSEL 1030 is the VCSEL described in Example 1, but the present invention is not limited thereto, and any VCSEL or VCSEL array described in Examples 1 to 8 may be used.

The VCSEL 1030 is a VCSEL described in the above examples that is mounted in a package. Each of the light-emitting side optical system 1040 and the light-receiving side optical system 1060 may be one convex lens type member, or may be configured with a lens group where a plurality of lenses are combined. The light-receiving image sensor 1070 is an image sensor in which a single photon avalanche diode (SPAD) photosensor is disposed in a two-dimensional array.

An outline of the operation of the ranging device 2000 follows. First a driving signal is outputted from the general control unit 1010 to the VCSEL driver 1020. The VCSEL driver 1020, which received the driving signal, injects a predetermined value of current to the VCSEL 1030 to oscillate the VCSEL 1030.

The laser light generated in the VCSEL 1030 contacts a measurement target 1200 via the light-emitting side optical system 1040, and the light reflected by the measurement target 1200 enters the light-receiving image sensor 1070 via the light-receiving side optical system 1060. In this way, the reflected light of the light emitted from the VCSEL 1030 is detected by each pixel of the light-receiving image sensor 1070. It does not matter whether the distance data processing unit 1080 and the light-receiving image sensor 1070 are disposed in a same package, or are mounted on different packages, and electrically connected via a circuit board, as long as the distance data processing unit 1080 is electrically connected to the light-receiving image sensor 1070.

An electric signal pulse outputted from each pixel of the light-receiving image sensor 1070 is inputted to the distance data processing unit 1080. The distance data processing unit 1080 calculates the distance information in the light propagating direction based on the timing (detection timing) of the electric signal pulse outputted from each pixel of the light-receiving image sensor 1070, and generates and outputs three-dimensional information thereof.

In this way, the ranging device 2000 can acquire and output the three-dimensional information.

The ranging device 2000 can be applied to control to prevent collision with another vehicle, and control for driving automatically following another vehicle, or the like, in the automobile field. Further, the ranging device 2000 can be used for a moving body (moving device) of a ship, airplane, an industrial robot, or the like, and a moving body detection system. Furthermore, the ranging device 2000 can be applied to various equipment that three-dimensionally recognizes an object, including distance information.

The application of the three-dimensional information is not limited to the above. For example, the distance information may be used for image processing. When a virtual object is superimposed and displayed on an acquired image of a real space, the virtual object can be displayed naturally on the image of the real world by using the three-dimensional information of the real space. Further, by acquiring the three-dimensional information simultaneously when an image is acquired, blurs can be corrected based on the three-dimensional information after the image is captured.

### Other Embodiments

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-000026, filed on Jan. 1, 2022, which is hereby incorporated by reference herein in its entirety.

What is claimed is:

1. A semiconductor light-emitting element having a structure in which a substrate, a first reflector, a resonator cavity including an active layer, a second reflector and a tunnel junction portion are stacked in this sequence, comprising:
a first current constriction portion configured with an oxidation constriction layer; and
a second current constriction portion including the tunnel junction portion,
wherein a width d2 of the second current constriction portion is smaller than a width d1 of the first current constriction portion.

2. The semiconductor light-emitting element according to claim 1,
wherein the tunnel junction portion is disposed on a part of an upper face of the second reflector, and
wherein a width of the tunnel junction portion is the width d2 of the second current constriction portion.

3. The semiconductor light-emitting element according to claim 2, wherein
the tunnel junction portion is included in a non-oxidized portion on the inner side of the oxidation constriction layer in the first current constriction portion in the planar view.

4. The semiconductor light-emitting element according to claim 2, wherein a transparent conductive film is formed on the tunnel junction portion, and on a portion of an uppermost portion of the second reflector on which the tunnel junction portion is not disposed.

5. The semiconductor light-emitting element according to claim 4, further comprising a transparent insulation film on the transparent conductive film1.

6. The semiconductor light-emitting element according to claim 2,
wherein the second reflector is configured with a p-type semiconductor,
wherein an n-type semiconductor layer is formed on the tunnel junction portion, and on a portion of an uppermost portion of the second reflector on which the tunnel junction portion is not disposed, and
wherein a third reflector is disposed on the n-type semiconductor layer.

7. The semiconductor light-emitting element according to claim 6, wherein the third reflector is configured with a semiconductor in which a plurality of layers are stacked.

8. The semiconductor light-emitting element according to claim 6, wherein the third reflector is configured with a dielectric in which a plurality of layers are stacked.

9. The semiconductor light-emitting element according to claim 2, wherein a fourth reflector is formed on the tunnel junction portion, and on a portion of an uppermost portion of the second reflector on which the tunnel junction portion is not disposed.

10. The semiconductor light-emitting element according to claim 2, further comprising a metal wiring, which is electrically connected to the tunnel junction portion, on the second reflector and on a part of the tunnel junction portion.

11. The semiconductor light-emitting element according to claim 10, wherein a reflectance is lower in a portion below the metal wiring on the second reflector than in the other portion.

12. The semiconductor light-emitting element according to claim 11, wherein the reflectance is lower in the portion below the metal wiring on the second reflector than in the other portion because an insulation film is disposed between the second reflector and the metal wiring.

13. The semiconductor light-emitting element according to claim 2, wherein the width d1 of the first current constriction portion satisfies 30 μm≤d1≤70 μm.

14. The semiconductor light-emitting element according to claim 1, further comprising:
an insulation film that is formed on an upper face of the tunnel junction portion and has an opening; and
a transparent conductive film that is formed on the tunnel junction portion at the opening,
wherein the width of the opening is the width d2 of the second current constriction portion.

15. The semiconductor light-emitting element according to claim 14, further comprising a transparent insulation film on the transparent conductive film.

16. The semiconductor light-emitting element according to claim 14, wherein the width d1 of the first current constriction portion satisfies 30 μm≤d1≤70 μm.

17. The semiconductor light-emitting element according to claim 2, further comprising a fifth reflector, formed of a dielectric multilayer film, on the second reflector.

18. The semiconductor light-emitting element according to claim 1, wherein the second reflector is a p-type semiconductor.

19. The semiconductor light-emitting element according to claim 1, wherein the thickness t of the tunnel junction portion satisfies 10 nm≤t≤440 nm.

20. A light-emitting device comprising a plurality of the semiconductor light-emitting elements according to claim 1.

21. A ranging device comprising:
a light source including the semiconductor light-emitting element according to claim 1;
a sensor that detects reflected light of light generated by the light source; and
a processing unit that acquires distance information based on a detection timing to detect the reflected light.
